(19) United States
(12) Patent Application Publication
(10) Pub. No.: US 2025/0151414 A1
(43) Pub. Date: May 8, 2025

(54) ZONAL INVERTER FOR PHOTOVOLTAIC SYSTEMS

(71) Applicant: Zonal Photon Conversion Inc., Portland, OR (US)

(72) Inventor: David Gershon, Portland, OR (US)

(73) Assignee: Zonal Photon Conversion Inc., Portland, OR (US)

(21) Appl. No.: 18/833,254

(22) PCT Filed: Feb. 7, 2023
(86) PCT No.: PCT/US2023/012542

§ 371 Date: Jul. 25, 2024

Related U.S. Application Data
(60) Provisional application No. 63/308,458, filed on Feb. 9, 2022.

(51) Int. Cl. H10F 10/161; H02J 3/38; H10F 19/75; H10F 77/00; H10F 77/20

(52) U.S. Cl. CPC H10F 10/161; H02J 3/388; H10F 19/75; H10F 77/215; H10F 77/244; H10F 77/937; H10F 77/939; H02J 2300/26

(57) ABSTRACT

Technology for converting electricity generated by photovoltaic cells to AC or DC output power is disclosed. In some examples of the disclosed technology, a zonal power inverter has a plurality of voltage converters, the outputs of the voltage converters being connected in series and being electrically isolated from one another except for their output terminals being connected in series. The power inverter can further comprise a DC/AC converter coupled to a positive output terminal of one of the voltage converters. In some examples, an isolated multi-junction photovoltaic cell includes a plurality of photosensitive semiconductor active layers, each of the active layers being electrically isolated from the other active layers, and formed from a respective material having a different band gap than the other active layers. In some examples, the multi-junction photovoltaic cell is coupled to the input of the zonal power inverter.

### CROSS-REFERENCE TO RELATED APPLICATIONS

This application claims the benefit of the earlier filing date of U.S. Provisional Application No. 63/308,458, filed Feb. 9, 2022, which application is incorporated herein by reference in its entirety.

### BACKGROUND

Many photovoltaic (PV) circuits include silicon PV cells, which are single junction (SJ) or first-generation semiconductor devices. The PV circuit is manufactured with a transparent top surface, an encapsulant film above and below electrically connected PV cells, a rear surface, and a frame around the outer edges. This structure protects the PV module from the environment, prevents electrical shock, and reduces thermal transfer from PV cells to environment. Under controlled testing criteria, best research PV-cell efficiencies are about 27%. Due to PV housing, differences in energy calculation methodology, and cell mismatches, module efficiencies decrease to about 2-4% lower than their single-cell efficiencies. Typically, PV modules operate in a temperature range of 15-65° C. As PV cell temperature increases, efficiency decreases about 0.4% per degree C. Thus, a PV cell at 50° C. has 10% lower power efficiency than when it is at 25° C. Thus, when deployed in the field, PV panels operate below 20% efficiency. Therefore, there is ample opportunity for improvement in the construction and use of PV cells and PV modules.

### SUMMARY

Methods and apparatus for converting electricity generated by photovoltaic cells to alternating current (AC) or direct current (DC) output power are disclosed.

In some examples of the disclosed technology, a zonal power inverter has a plurality of voltage converters, the outputs of the voltage converters being connected in series, each of the voltage converters being electrically isolated from one another except for their output terminals being connected in series. The power inverter can further comprise a DC/AC converter coupled to a positive output terminal of one of the voltage converters and a negative output terminal of one of the voltage converters. The power inverter can further comprise a plurality of photovoltaic (PV) cells, each of the PV cells having a cathode coupled to an input of a respective one of the voltage converters. The power inverter can further comprise a controller coupled to the respective control inputs of the voltage converter switches, the controller being programmed to modulate each of the respective control inputs to regulate output voltage at the respective output terminal the voltage converters.

In some examples of the apparatus, at least one of the voltage converters is a flyback DC/DC converter. In some examples, the apparatus further comprises a transformer and a switch, the switch being operated by the controller to modulate operation of its respective power converter.

In some examples of the disclosed technology, a method of operating a zonal power converter includes, with a controller, modulating input signals to a plurality of voltage converters coupled in series, each of the plurality of voltage converters being electrically isolated except for the series coupling and being configured to receive power from a respective photovoltaic (PV) cell of a plurality of photovoltaic cells.

In some examples of the disclosed technology, an isolated multi-junction photovoltaic (PV) cell includes a plurality of photosensitive semiconductor active layers, each of the active layers being electrically isolated from the other active layers, and formed from a respective material having a different band gap than the other active layers. In some examples, the PV cells includes at least one of an active layer comprising at least one of: boron phosphide, selenium, La₂CuO₂, or gallium indium phosphide; an active layer comprising at least one of: gallium arsenide, cadmium telluride, or copper zinc tin sulfide; an active layer comprising at least one of silicon, tin sulfide, or Zn₃As₂; or an active layer comprising at least one of germanium, indium nitride, or gallium antimonide.

### BRIEF DESCRIPTION OF THE DRAWINGS

FIG. 1 is a block diagram of a system including a power inverter for use with photovoltaic cells, as can be implemented in certain examples of the disclosed technology.

FIGS. 2A-2B is a simplified schematic of a photovoltaic converter system as can be implemented in certain examples of the disclosed technology.

FIG. 3 is a cross-sectional diagram (not to scale) showing a multi-junction photovoltaic cell, as can be implemented in certain examples of the disclosed technology.

FIG. 4 is a plan view of a semiconductor wafer showing an example arrangement of fingers/trenches and busbars as can be implemented in certain examples of the disclosed technology.

FIG. 5 illustrates a cross-section of a region of the PV cell having a via region used to electrically connect the busbars to the top surface of the cell so that it can be connected to a voltage converter. As shown, each of the vias connects to a different layer of the busbar, thereby connecting to a different respective terminal of the photodiode.

FIG. 6. illustrates a cross-section of a multi-junction PV cell and indicates a via region at the edge of the wafer. The vias connect each side of the active regions to the top surface of the cell.

FIG. 7 illustrates a cross-section of a multi-junction PV cell. The PV cell is formed by separately manufacturing a set of glass, TCO, and active photodiode layers and combining the junction layers. External leads for each junction connect to an independent electrically isolated DC-DC converter.

FIG. 8 is a chart plotting the voltage across a photodiode on the x-axis versus the short circuit current density on the on the y-axis for three different photodiode materials.

FIG. 9 is a chart plotting the power output of a photovoltaic cell vs. voltage across the photodiode.

FIG. 10 is a flow chart outline an example method of operating a power converter with a controller.

FIG. 11 illustrates a generalized example of a suitable computing environment in which described embodiments, techniques, and technologies, including implementing microcontrollers for a power inverter, can be implemented.

FIG. 12 is a simplified schematic of a photovoltaic converter system including a multi-input transformer, as can be implemented in certain examples of the disclosed technology.

FIG. 13 is a simplified schematic of a photovoltaic converter system including multiple groups of drivers, as can be implemented in certain examples of the disclosed technology.

### DETAILED DESCRIPTION

### I. General Considerations

This disclosure is set forth in the context of representative embodiments that are not intended to be limiting in any way.

As used in this application the singular forms “a,” “an,” and “the” include the plural forms unless the context clearly dictates otherwise. Additionally, the term “includes” means “comprises.” Further, the term “coupled” encompasses electrical and magnetic ways of coupling or linking items together, and does not exclude the presence of intermediate elements between the coupled items. Furthermore, as used herein, the term “and/or” means any one item or combination of items in the phrase.

The systems, methods, and apparatus described herein should not be construed as being limiting in any way. Instead, this disclosure is directed toward all novel and non-obvious features and aspects of the various disclosed embodiments, alone and in various combinations and subcombinations with one another. The disclosed systems, methods, and apparatus are not limited to any specific aspect or feature or combinations thereof, nor do the disclosed things and methods require that any one or more specific advantages be present or problems be solved. Furthermore, any features or aspects of the disclosed embodiments can be used in various combinations and subcombinations with one another.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed things and methods can be used in conjunction with other things and methods. Additionally, the description sometimes uses terms like “produce,” “generate,” “output,” “receive,” “follow,” “select,” and “output” to describe the disclosed methods. These terms are high-level descriptions of the actual operations that are performed. The actual operations that correspond to these terms will vary depending on the particular implementation and are readily discernible by one of ordinary skill in the art.

Theories of operation, scientific principles, or other theoretical descriptions presented herein in reference to the apparatus or methods of this disclosure have been provided for the purposes of better understanding and are not intended to be limiting in scope. The apparatus and methods in the appended claims are not limited to those apparatus and methods that function in the manner described by such theories of operation.

Any of the disclosed methods can be implemented as computer-executable instructions stored on one or more computer-readable media (e.g., computer-readable media, such as one or more optical media discs, volatile memory components (such as DRAM or SRAM), or nonvolatile memory components (such as hard drives)) and executed on a computer (e.g., any commercially available computer, including smart phones or other mobile devices that include computing hardware). Any of the computer-executable instructions for implementing the disclosed techniques, as well as any data created and used during implementation of the disclosed embodiments, can be stored on one or more computer-readable media (e.g., computer-readable storage media). The computer-executable instructions can be part of, for example, a dedicated software application, or a software application that is accessed or downloaded via a web browser or other software application (such as a remote computing application). Such software can be executed, for example, on a single local computer (e.g., with general-purpose and/or specialized processors executing on any suitable commercially available computer) or in a network environment (e.g., via the Internet, a wide-area network, a local-area network, a client-server network (such as a cloud computing network), or other such network) using one or more network computers.

For clarity, only certain selected aspects of the software-based implementations are described. Other details that are well known in the art are omitted. For example, it should be readily understood to one of ordinary skill in the art having the benefit of the present disclosure that the disclosed technology is not limited to any specific computer language or program. For instance, the disclosed technology can be implemented by software written in C, C++, Java, or any other suitable programming language. Likewise, the disclosed technology is not limited to any particular computer or type of hardware. Certain details of suitable computers and hardware are well-known and need not be set forth in detail in this disclosure.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, and infrared communications), electronic communications, or other such communication means.

### II. Introduction to the Disclosed Technology

Methods and apparatus for converting electricity generated by photovoltaic cells to AC or DC output power are disclosed. Solar power generation directly converts solar radiation into electrical energy using photovoltaic cells. Incident photons can be absorbed within a semiconductor material (e.g., a PV cell), which excites electrons from valence to conduction bands and holes from conduction to valence bands, respectively, to produce electric charge. A P-N junction separates electrons and holes in the PV cell to produce voltage and electrical power.

Photovoltaic cells can be combined into “PV modules.” A PV module electrically connects a plurality of individual PV cells to increase total output voltage and power. The DC output power generated can be connected to an inverter (e.g., a microinverter), which transforms the DC output power into a desired AC signal. PV module efficiency depends upon each cell's I-V characteristics, maximum power point (MPP) of combined PV cells, and DC-to-AC conversion methodology. Photovoltaic cell efficiency may diminish from factors including: increasing PV cell temperature, higher variability of incident radiation, and cell imperfections or failure modes. These factors contribute to mismatches between each cell's I_{sc} (short circuit current) and its V_{oc} (open circuit voltage). When PV cells or modules are electrically connected in series, total current through the circuit is limited by the lowest I_{sc} of all of the series PV cells, which diminishes overall output power.

In some examples of the disclosed technology, multi-junction solar cells are used. A multi-junction (MJ) solar cell is a vertical stack of several semiconductor P-N junctions, each of which have different bandgaps. Incident radiation is initially absorbed by top layer, which has largest bandgap. Unabsorbed and lower frequency radiation will propagate to lower layers, which has successively lower bandgaps. Compared to a single-junction cell, each layer or P-N junction in a MJ solar cell will more effectively convert energy for a range of wavelengths.

The impact of current mismatch between PV cells or PV modules can be reduced by using PV cells or selecting/modifying layers of a multijunction cell to have similar I_{sc}. Existing PV panel designs do not allow for direct, non-insulated cooling of heated PV cells. A regional (zonal) energy extraction from PV cells eliminates this current mismatch and allows direct thermal cooling of cells.

In some examples of the disclosed technology, PV cells can provide charge output to an electrically isolated DC-DC converter; each PV cell or zone (e.g., in a multi-junction cell) is connected to its own converter. In some examples, the DC-DC converter is a flyback converter. The outputs of the converters are connected in series. Each of the converters has a flyback or boost switch that oscillates responsive to an input signal. The switch can be implemented using, for example, depletion mode transistors or microelectromechanical (MEM) switches. In other examples, a relay is used. For example, a microcontroller can use pulse width modulation to vary the duty cycle of the input signal and hence control the output voltage of the converter. It is often desirable to operate the converter at or near its maximum power point by adjusting the input signal. As will be readily understood to a person of ordinary skill in the art having the benefit of the present disclosure, the output voltage associated with the maximum power point will vary dynamically, as operating conditions of the PV cells and load vary over time. Thus, the target output voltage will be dynamically adjusted over time. (For example, using a perturb and observe operations as discussed further below). By using DC-DC converters configured as described in certain examples herein, each PV cells can be allowed to operate at or near their maximum current and not be limited by minimum operating current in connected PV cells.

Power from the series connected converter outputs can then be transferred to a DC battery system or to a DC/AC converter. For example, an H-bridge converter can be used to convert the DC power to an AC signal.

### III. Example Converter System

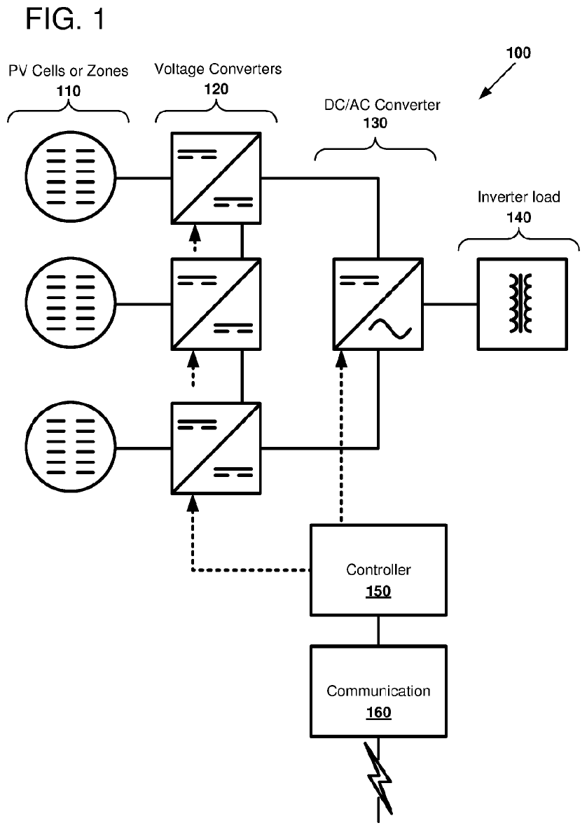

FIG. 1 is a block diagram of a system including a power inverter 100 for use with photovoltaic cells, as can be implemented in certain examples of the disclosed technology. A plurality of photovoltaic cells or zones 110 are shown. In some examples, single junction photovoltaic cells are used. In other examples, multi-junction photovoltaic cells are used. Each cell or zone of a multi-junction photovoltaic cell has an output connected to the input terminals of one of the voltage converters 120 shown. The voltage converters can be any suitable DC-DC converter with electrical isolation, including any combination of the following types of converters: flyback, isolated ĆUK, isolated SEPIC (single-ended primary-inductor converter), Zeta (inverse SEPIC), push-pull, forward, dual-active bridge (DAB), dual-half bridge, half-full bridge, or multiport DAB. The voltage converters 120 have their outputs connected and in series. The first and last voltage converter outputs are connected to the input terminals of a DC/AC converter 130. The DC/AC converter outputs an AC wave form to the inverter load 140.

Each of the voltage converters 120 receives an input signal from a controller 150. The controller 150 modulates the input signals to each converter to control when a circuit is completed to the respective PV cells. The input signals or modulated to optimize the power output of each individual PV cell. The voltage converters are otherwise isolated from each other. Because of this isolation, the current output of the voltage converter stack is not limited by any one particular PV cell. The controller 150 can also communicate with wired or wireless communication networks and other hardware using the communication module 160. In some examples, the controller is a dedicated PID or PI controller, a microcontroller, a microprocessor field-programmable gate array (FPGA), or an ASIC-based controller.

The controller and power electronics for one or more PV cells or zones can be combined into a PV module. For example, the components can be attached to a printed circuit board (PCB). As will be readily understood to one of ordinary skill in the art having the benefit of the present disclosure, the PCB can have additional switches and diodes for each PV zone implement it with the module. The module can further comprise electromagnetic interference (EMI) suppression filters at the output of the AC converter. The PV module can include integrated arc fault protection and rapid shutdown capabilities to comply with applicable electrical standards. Because the PV cells or zones are electrically isolated, the cells may be cooled with gas or liquid (e.g., air or water) applied to the PV cell package without creating short circuits through the coolant.

### IV. Example Zonal Inverter System Using Flyback Converters

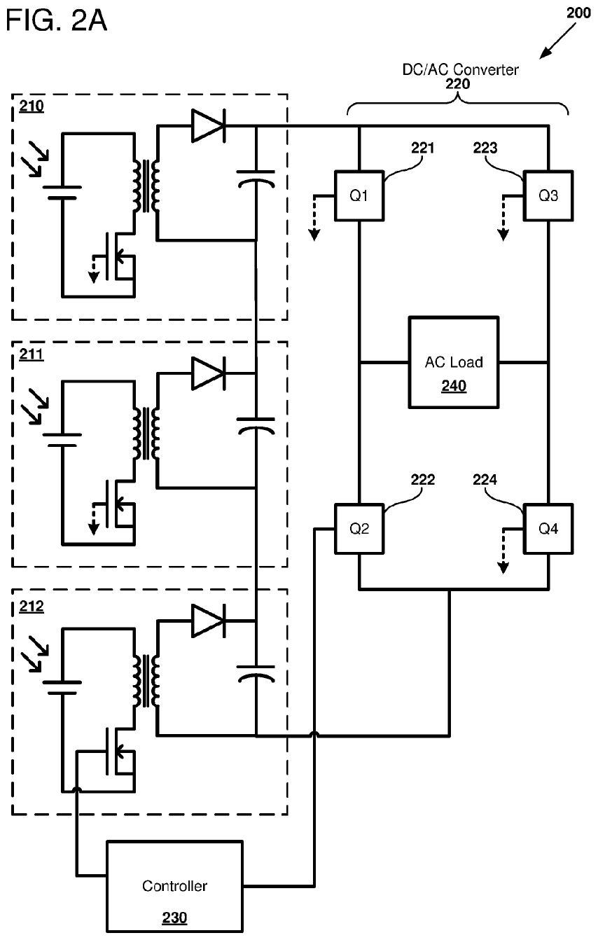

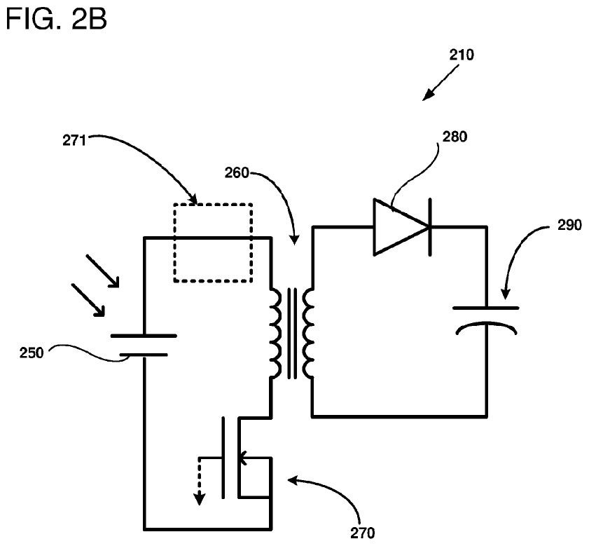

FIGS. 2A and 2B are a simplified schematic of a photovoltaic converter system 200 as can be implemented in certain examples of the disclosed technology. As shown, there are three flyback converter units 210, 211, 212. Each of the converter units is coupled to a photovoltaic cell which produces charge in response to incident photons received at the active layer(s) of the cell. The photovoltaic cell acts as a variable DC voltage source. This voltage source is coupled to the primary coil of a transformer. The other end of the primary coil is coupled to a switch. When the switch is closed, it completes the circuit to the other terminal of the PV cell.

Each of the flyback converters 210, 211, 212 are electrically isolated from each other. As shown, each PV cell or PV zone connects only to its respective voltage converter. When the flyback converters switch is open, the respective PV cell is not electrically connected to its transformer. The controller 230 modulates an input signal to each of the flyback converter switches to cause the switches to open and close. The controller attempts to optimize the power output of each PV cell, as will be described in further detail below. The controller 230 also modulates input to the DC/AC converter. In this example, a H-Bridge style DC/AC converter 220 is used, although as will be readily understood to one of ordinary skill in the art, other DC/AC converter circuits may be used. For example, a cascaded H-bridge converter can provide the DC/AC converter. The depicted DC/AC converter includes four switches 221-224 and is coupled to an AC output load 240.

In some examples, the controller is a processor or microcontroller executing computer-readable instructions stored in a memory. In other examples, a finite state machine or other control logic is provided by a custom circuit or programmable logic. The controller can be configured to measure a combined output DC signal of the series DC/DC converters, or to measure output voltages and/or current for individual converters. As will be readily understood to one of ordinary skill in the art having the benefit of the present disclosure, the controller can use suitable techniques to control operation of the converters, for example, proportional-integral-derivative (PID) or proportional-integral (PI) techniques.

When the controller is configured to measure a combined output DC signal, the controller can generate separate pulse width modulation (PWM) signals to each of the flyback switches. During a certain time period, the controller will adjust PWM signal to one of the flyback switches and measure total output power. All other flyback switches will retain their prior PWM signal. Using a perturb and observe algorithm, the controller system will determine the next PWM signal for another of the flybacks. In some examples, the controller will continue to adjust PWM until MPP is found for the present switch. Then, the controller will proceed to find new MPP for the next flyback switch. Controller incrementally drives to MPP of each PV zone.

In another configuration, a controller reads relative voltage of each zonal output. Hall current sensors measure each output current, which is then read by controller. The controller generates control signals (e.g., PWM signals) to each flyback switch. The controller reads voltage and current (to calculate power) of each zone repeatedly. The system can then separately adjust the control signal for each flyback signal. For example, a perturb and observe approach can be used to select a control signal that will operate the converter, so the PV cell operates at or near its maximum power point.

Turning to FIG. 2B, additional details of one of the flyback converters 210 is shown. The terminals of a PV cells are coupled to a first terminal of the primary coil of a transformer 260. A second terminal of the primary coil is electrically connected to a switch 270. The switch can be, for example, a field effect transistor (FET) such as a metal-oxide-semiconductor FET (MOSFET), for example, depletion mode or enhancement mode FETs or MOSFETs. Using such transistors may be desirable to avoid voltage loss across the source/drain (or collector/emitter) of the of the FET when the device is active. The source of the switch transistor connects to a second terminal of the primary coil of the transformer and the drain connects to the negative terminal of the PV cell 250. The flyback converter 210 further includes a diode 280 connected a first terminal of the secondary coil of the transformer 260 and providing output voltage for the individual flyback converter. A capacitor 290 is provided across the output terminals of the flyback converter. In some examples, another switch, configured to operate in opposite phase of switch 270, or a diode and switch in parallel, can used to implement the flyback converter. In some examples, the switch 270 is included in the circuit at the alternate location 271 shown, between the output of the PV cell and the top coil of the transformer 260 primary input.

### V. Example Multi-Junction Photovoltaic Cell

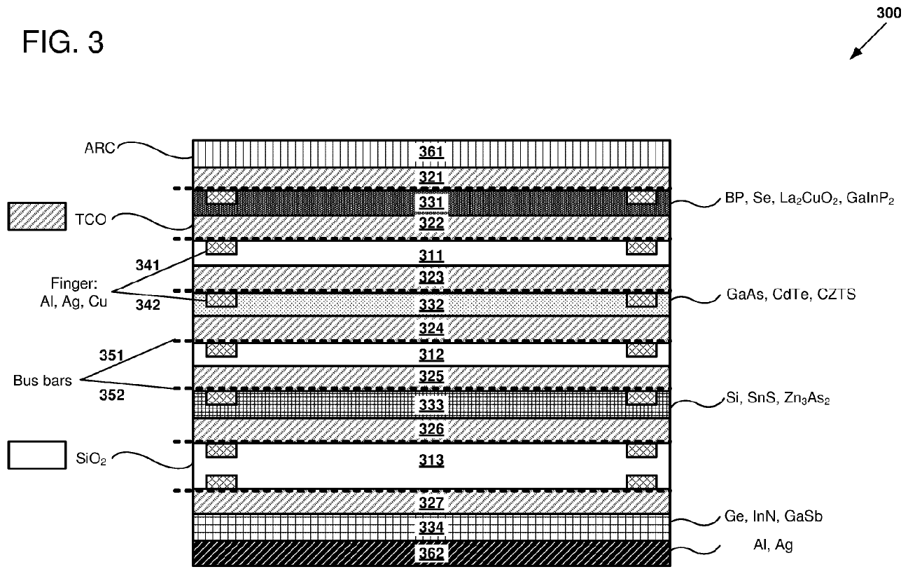

FIG. 3 is a cross-sectional diagram (not to scale) showing a multi-junction photovoltaic cell 300, as can be implemented in certain examples of the disclosed technology. As shown, the cell includes multiple layers of silicon dioxide 311-313 and transparent conductive oxide (TCO) 321-327. The cell also includes a number of active layers 331-334 which form photodiodes. In this example, the planar surfaces of the active layers form a cathode terminal and an anode terminal of the photodiode. The terminals of the photodiode are in electrical contact with metal conductors as shown. The conductors can be made from, for example, aluminum, silver, or copper with an antidiffusion liner. A portion of the conductors form trenched fingers (e.g., trenched fingers 341, 342 formed from at least one of aluminum, silver, or copper) in the active layer or insulation silicon dioxide layer. The bus bars (or “conductor busses”) (e.g., bus bars 351, 352) are indicated by dashed lines and are sandwiched between layers as shown in FIG. 3.

The materials for the active layers are selected to have non-overlapping bandgaps. This helps improve power output, as each of the active layers is sensitive to a particular frequency range of electromagnetic energy (e.g., a range of spectra of visible light or ultraviolet light). In the illustrated example, there are four photovoltaic active layers shown. The first active layer 331 is a semiconductor formed from at least one of: boron phosphide, selenium, La₂CuO₂, or gallium indium phosphide. The second active layer 332 is a semiconductor formed from at least one of: gallium arsenide, cadmium telluride, or copper zinc tin sulfide (CZTS). The third active layer 333 is a semiconductor formed from at least one of: silicon, tin sulfide, or Zn₃As₂. The fourth active layer 334 is a semiconductor formed from at least one of germanium, indium nitride, or gallium antimonide. As will be readily understood by one of ordinary skill in the art having the benefit of the present disclosure, any suitable combination of active layers can be selected for the multi-junction PV cell. For example, some cells may have just one of the preceding active layers, or a combination of two, three, or four of the preceding active layers. The thicknesses of the semiconductor layers are selected to maximize light absorption for specified frequency range and to minimize reflection between layers.

The silicon dioxide layers 311-313 insulate between the layers disposed above and below the insulating layers. The silicon dioxide layers 311-313 further provide structural support for the active layers. The TCO layers 321-327 form a conductive plane over the surface of respective active layers 331, 332, 333, 334, but also allow light to pass through the TCO layer. In this example, the multi-junction device includes an anti-reflective coating (ARC) 361 on the top layer and a conductive planar layer 362 on the bottom layer (e.g., formed from aluminum or silver).

As will be readily understood to a person of ordinary skill in the relevant art having the benefit of the present disclosure, in other examples, additional electrically-isolated active photovoltaic layers beyond the four active layers shown in in FIG. 3 can be used in a multi-junction cell. In some examples, a multi-junction cell includes only a single active layer, a pair of active layers, or a triplet of the active layers shown in FIG. 3.

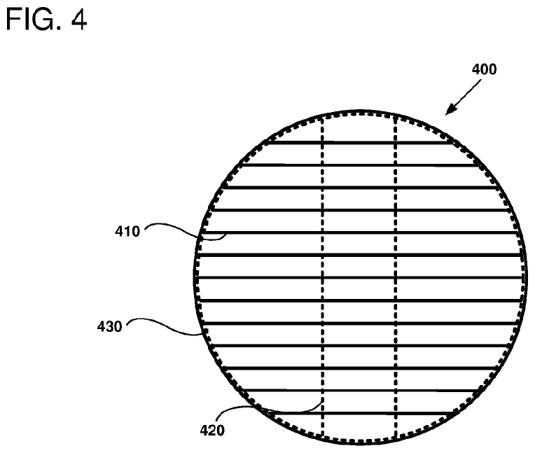

FIG. 4 is a plan view of a semiconductor wafer 400 showing an example arrangement of fingers/trenches 410 and busbars 420 as can be implemented in certain examples of the disclosed technology. The wafer further has an outer ring busbar 430 as shown.

An example of manufacturing a multi-junction cell is described next. As will be readily understood to one of ordinary skill in the art having the benefit of the present disclosure, the manufacturing process can be adapted depending on the particular cell being manufactured.
A silicon substrate is provided and cleaned.
Resist is deposited and aligned mechanical with wafer edge notches.
Metal trenches and busbars are mechanically patterned (e.g., using imprint lithography)
Reactive Ion Etch (RIE) is used transfers patterns into Si material. Resist and etch byproduct are cleaned off.
These etched structures are then filled with liner/metal and overburden metal is polished. Liner prevents metal from diffusing into semiconductor material.
Transparent conducting oxide TCO layer is deposited.
A glass layer is then deposited.
Next, resist is deposited. The wafer is mechanically aligned with first trench patterning.
Metal trenches and busbars are mechanically patterned.
Reactive Ion Etch (RIE) transfers pattern into glass. Resist and etch byproduct are cleaned off. These etched structures are then filled with metal and overburden metal is polished.
Next, a TCO layer is deposited.
A P-doped semiconductor, which has a larger bandgap than a lower layer, is deposited and then the same semiconductor with N-doping is deposited. This will form a P-N junction forming a photodiode. Any of the layers described for the active layers of FIG. 3 can be used to form the photodiode.
Next, resist is deposited. The wafer is mechanically aligned with prior trench patterning. Metal trenches and busbars are mechanically patterned.
RIE is used to etch a pattern into semiconductor. Resist and etch byproduct are cleaned off. These etched structures are then filled with liner and metal. Overburden metal is polished.
Next, a TCO layer is deposited.
A glass layer is then deposited.
Higher layers can be subsequently fabricated by repeating the previous acts of depositing a glass layer, forming trenches and busbars, depositing a TCO layer, forming a photodiode active layer, and so forth.
For the top layer having largest bandgap material, an anti-reflective coating (ARC) is applied on the highest TCO layer.
After forming the top active layers (e.g., first three active layers described with reference to FIG. 3, the wafer can be flipped over and the obverse surface is cleaned again.
Another active layer can be formed. First, TCO layer and then glass layer are deposited.
Resist is deposited.
The wafer is mechanically aligned with trench patterning of the other side.
Metal trenches and busbars are mechanically patterned.
RIE etches pattern through glass to Si. Resist and etch byproduct are cleaned off.
These etched structures are then filled with liner and metal. Overburden metal is polished.
Another layer of glass is deposited.
The wafer is mechanically aligned with prior trench patterning.
Metal trenches and busbars are mechanically patterned.
RIE etches pattern into glass. Resist and etch byproduct are cleaned off.
These etched structures are then filled with metal and overburden metal is polished.
TCO is layer is deposited.
A fourth active layer is formed with an N-doped semiconductor being deposited and then the same semiconductor with P-doping being deposited.
A metal film (e.g., of aluminum or silver) can be applied or deposited on last layer.

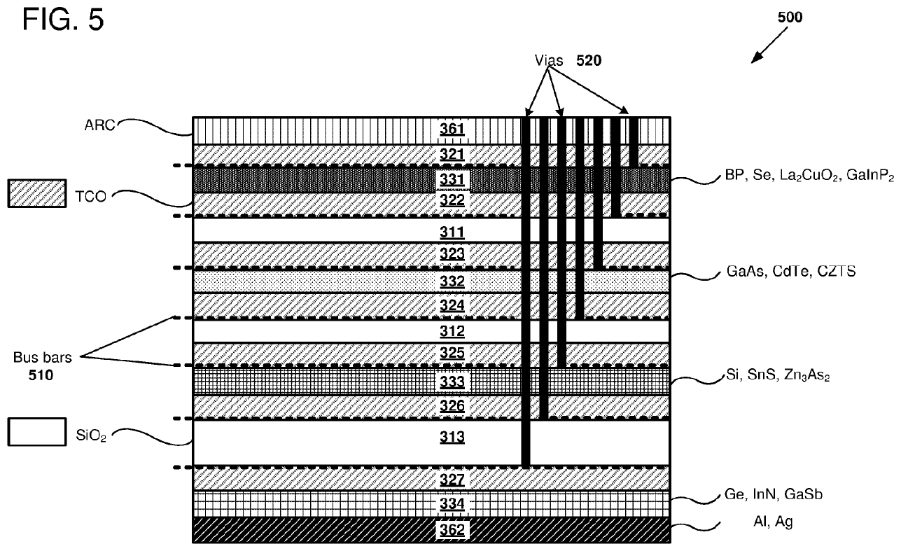

FIG. 5 illustrates a cross-section of a region of a multi-junction PV cell 500 having a via region used to electrically connect the bus bars (indicated by dashed lines, such as at reference 510) to the top surface of the cell so that it can be connected to a voltage converter. As shown, each of the vias 520 connects to a different layer of the busbar, thereby connecting to a different respective terminal of the photodiode. The layers shown are composed and arranged the same as the layers discussed above regarding FIG. 3. As will be readily understood to a person of ordinary skill in the art having the benefit of the present disclosure, the composition, number, and arrangement of layers in the PV cell can be varied in a similar fashion as discussed above.

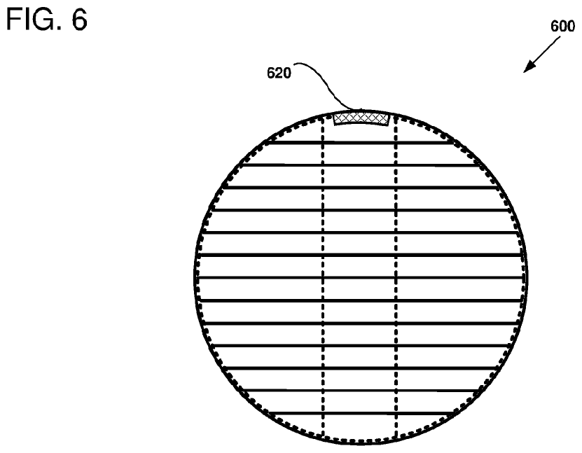

FIG. 6. illustrates a via region 620 at the edge of a wafer 600. The vias can be formed after manufacturing the PV cell by the following actions:
The wafer is flipped over again and aligned.
On the wafer edge, large vias are patterned. Multistep RIE cuts through various layers of insulating and semiconductor material. The via etch will stop when it contacts edge metal busbars. Other vias will continue to etch until they reach their desired edge busbar.
In an alternative example, laser etching is used to drill vias to the various layer busbars.
The wafer is cleaned. A thin oxide film is deposited on via sides and busbar. RIE anisotropically etch breaks through oxide on via bottoms. Metal fills vias and electrical connection can be made to PCB metal lines.

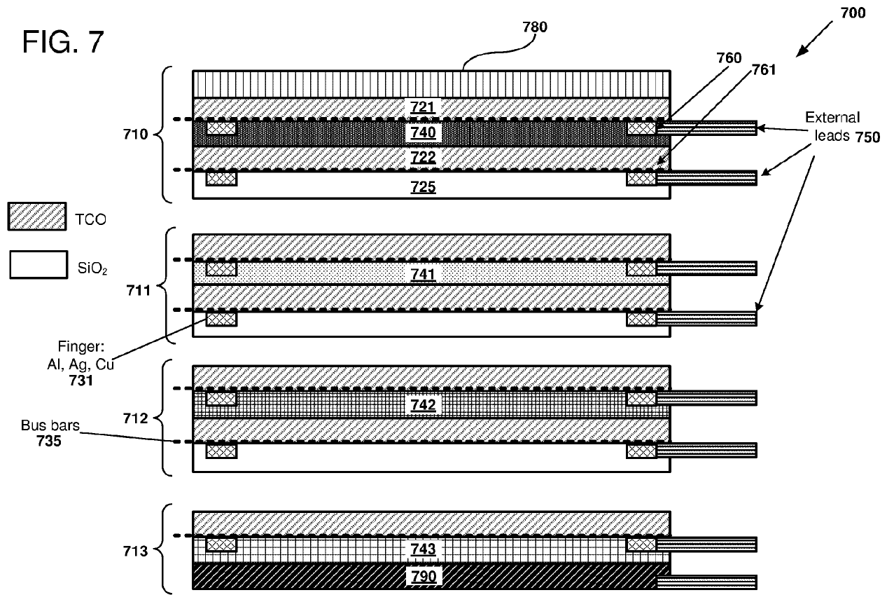

FIG. 7 illustrates a cross-section of a multi-junction PV cell 700. The PV cell is formed by separately manufacturing a set of glass, TCO, and active photodiode layers 740-743 and combining the junction layers. In this example, each set 710, 711, 712, 713 of junction layers is made separately on thin sheets of film. For example, junction layer set 710 includes TCO layers 721, 722, insulating layer 725, and active photodiode layer 740. The junction layer sets are placed on top of each other and aligned. Similar to those discussed in FIG. 3, conductors form trenched fingers (e.g., trenched finger 731 formed from at least one of aluminum, silver, or copper) in the active layer or insulation silicon dioxide layer. The bus bars (e.g., bus bars 735) are indicated by dashed lines and are sandwiched between layers as shown. External leads 750 are connected to both ends of the junction layer (e.g., as shown at 760, 761 for junction layer set 710) or the PV cell backside (790). After the layers are aligned, vacuum sealing and an adhering sealing agent are applied to the PV cell. An anti-reflective coating 780 can be applied to the first junction layer set 710.

The metal trenches in the multi-junction PV cells can be made out silver, aluminum, or copper. After trench etch into semiconductor material and prior to metal fill, trench bottoms can be implanted with N dopants on the N-type side and P dopants for the P-type side of the semiconductor layer.

An insulating layer (e.g., glass, SiO2)—provides electrical isolation between semiconductor layers. Other wide bandgap dielectric material can be used. The dielectric constant of each insulating layer will be selected to minimize light reflection at interface layers.

In various examples, disclosed multi-junction PV cells may have 4-6 different bandgaps. In one example, a five-junction PV cell could be made of active layer materials having 0.73 eV (GaSb) or 0.67 eV bandgap (Ge), 1.12 eV bandgap (Si), 1.43 eV bandgap (GaAs), 1.68 eV bandgap (CuGaSe₂), and 2.1 eV (GaInP). In another example, a six-junction PV cell could be made of made of active layer materials having 0.73 eV (GaSb) or 0.67 eV bandgap (Ge), 0.91 eV bandgap (Cu₂SnS₃), 1.12 eV bandgap (Si), 1.43 eV bandgap (GaAs), 1.68 eV bandgap (CuGaSe₂), and 2.1 eV bandgap (GaInP).

In some examples, disclosed multi-junction PV cells may have 2-6 different bandgaps. For example, a 2-layer multi junction PV cell can have (1) an active layer comprising at least one of: boron phosphide, selenium, lanthanum copper oxide, selenium, cadmium selenide, Perovskite, copper indium gallium diselenide (CIGS), aluminum antimonide, tin sulfide, zinc phosphide, cadmium telluride, copper zinc tin sulfide (CZTS), gallium arsenide, or indium phosphide, and (2) an active layer comprising at least one of tin sulfide, boron arsenide, silicon, copper zinc tin sulfur selenide (CZTSSe), copper indium selenide (CIS), zinc arsenide, iron disulfide, copper tin sulfide (CTS), silver sulfide, gallium antimonide, indium nitride, or germanium. As another example, a 3-layer multi junction PV cell can have an active layer comprising at least one of: Copper (I) oxide, Aluminum arsenide, gallium indium phosphide (GaInP), Zinc diphosphide, gallium selenide, selenium, boron phosphide, or lanthanum copper oxide (La₂CuO₂); an active layer comprising at least one of: selenium, cadmium selenide, Perovskite, copper indium gallium diselenide (CIGS), aluminium antimonide, tin sulfide, zinc phosphide, cadmium telluride, or copper zinc tin sulfide (CZTS); and an active layer comprising at least one of tin sulfide, boron arsenide, silicon, copper zinc tin sulfur selenide (CZTSSe), copper indium selenide (CIS), zinc arsenide, iron disulfide, copper tin sulfide (CTS), silver sulfide, gallium antimonide, indium nitride, or germanium. As another example, a 4-layer multi junction PV cell can have an active layer comprising at least one of: an active layer comprising at least one of: boron phosphide, Lanthanum copper oxide, selenium, cadmium selenide, Perovskite, or copper indium gallium diselenide (CIGS); an active layer comprising at least one of: cadmium telluride, copper zinc tin sulfide, gallium arsenide, or indium phosphide; an active layer comprising at least one of Tin sulfide, Boron arsenide, Silicon, copper zinc tin sulfur selenide (CZTSSe), Copper indium selenide (CIS), Zinc arsenide, Iron disulfide, copper tin sulfide (CTS), or silver sulfide; and an active layer comprising at least one of gallium antimonide, indium nitride, or germanium. As another example, a 5-layer multi junction PV cell can have an active layer comprising at least one of: an active layer comprising at least one of: Copper (I) oxide, Aluminum arsenide, gallium indium phosphide (GaInP), zinc diphosphide, gallium selenide, selenium, boron phosphide or lanthanum copper oxide (La₂CuO₂); an active layer comprising at least one of: selenium, cadmium selenide, Perovskite, copper indium gallium diselenide (CIGS), or aluminum antimonide; an active layer comprising at least one of: gallium arsenide, indium phosphide or uranium dioxide; an active layer comprising at least one of copper sulfide, copper oxide, tin sulfide, boron arsenide, silicon or copper zinc tin sulfur selenide (CZTSSe); and an active layer comprising at least one of copper indium selenide (CIS), zinc arsenide (Zn₃As₂), iron disulfide, copper tin sulfide (CTS), silver sulfide, gallium antimonide, indium nitride, or germanium. As another example, a 6-layer multi junction PV cell can have an active layer comprising at least one of: an active layer comprising at least one of: copper (I) oxide, aluminum arsenide, gallium indium phosphide (GaInP), zinc diphosphide, gallium selenide, selenium, boron phosphide or lanthanum copper oxide (La₂CuO₂); an active layer comprising at least one of: selenium, cadmium selenide, Perovskite, copper indium gallium diselenide (CIGS), or aluminum antimonide; an active layer comprising at least one of: gallium arsenide, Indium phosphide or uranium dioxide; an active layer comprising at least one of copper sulfide, copper oxide, tin sulfide, boron arsenide, silicon, or copper zinc tin sulfur selenide (CZTSSe); an active layer comprising at least one of copper indium selenide (CIS), zinc arsenide (Zn₃As₂), iron disulfide, copper tin sulfide (CTS), or silver sulfide; and an active layer comprising at least one of gallium antimonide, indium nitride, or germanium. As another example, a 4-layer multi junction PV cell can have an active layer comprising at least one of: an active layer comprising at least one of: boron phosphide, selenium, La₂CuO₂, or gallium indium phosphide; an active layer comprising at least one of: gallium arsenide, cadmium telluride, or copper zinc tin sulfide; an active layer comprising at least one of silicon, tin sulfide, or Zn₃As₂; and an active layer comprising at least one of germanium, indium nitride, or gallium antimonide.

In another example, a two-junction PV cell could be made of active layer materials having 1.12 eV bandgap (Si), 1.43 eV bandgap (GaAs) or 1.5-2.3 eV bandgap (Perovskite).

In another example of fabricating an electrically isolated, multi-junction cell, the following actions are performed:
For the bottom layer, aluminum film produced and cut to size.
P-doped semiconductor, which has a lowest bandgap is deposited and then the same semiconductor with N-doping is deposited.
Resist film is then deposited. Trenches and busbars are mechanically patterned. In the semiconductor layer, trenches are etched and cleaned. These etched structures are then filled with liner/metal. Overburden metal is polished. Electrical leads can be connected to edge busbar.
TCO layer is deposited.
For all layers above the lowest, the following actions can be performed
An insulating film is deposited on the substrate. Glass film should have a dielectric constant similar or between final adjacent semiconductor dielectric constants.
Resist is spun on glass. Trenches (fingers) and busbars are mechanically patterned on glass. These standard patterns are etched into glass and cleaned. These etched structures are then filled with metal. Overburden metal is polished. Electrical leads can be connected to edge busbar.
TCO is then deposited. P-doped semiconductor is deposited as the active layer and then the same semiconductor with N-doped is deposited as another portion of the active layer.
Resist film is then deposited. Based on prior patterning, the film can be aligned and mechanically patterned with trenches and busbars. In a semiconductor layer, trenches are etched and cleaned. These etched structures are then filled with liner/metal. Overburden metal is polished. Electrical leads can be connected to edge busbar.
Another layer of TCO is deposited.
On top surface of TCO and largest bandgap material, anti-reflective coating (ARC) is applied.

In this example, the multi-junction cell is then assembled with lowest bandgap layer on bottom. Subsequent layers have increasing larger bandgaps. Alignment of trenches between layers is critical to minimize shading of lower layers. These separate films are permanently bonded to avoid moisture intrusion, film delamination, and misalignment between layers.

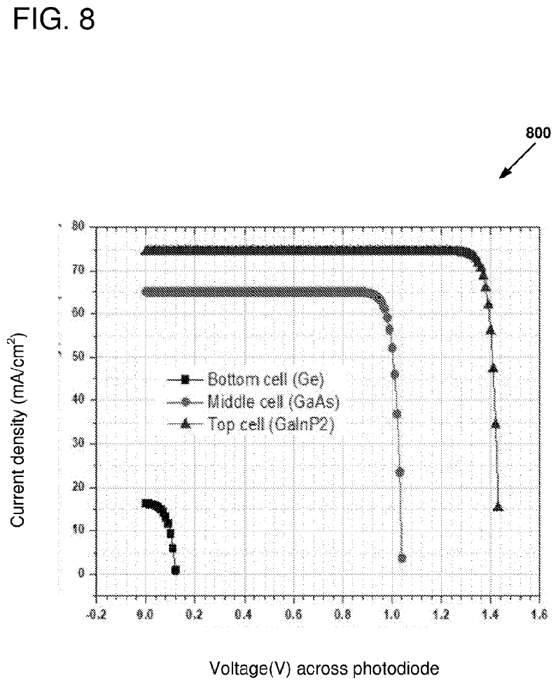

FIG. 8 is a chart 800 plotting the voltage across the photodiode on the x-axis versus the current density on the on the y-axis for three different photodiode materials, adapted from Kowsar et al., “Comparative Study on Solar Cell Simulators,” Int'l Conf. on Innovation in Engr, and Tech. (ICIET) 1-6, (IEEE 2019). Each of the PV cells is made using a different active semiconductor layer, in this example, germanium, gallium arsenide, and gallium indium phosphide, which layers can be combined into a multi-junction PV cells as discussed above. As shown, when exposed to light, each of the materials exhibit different current vs. voltage relationships. Thus, in order to provide maximum current, each of the layers should operate at a varying voltage or maximum power point (MPP). This MPP depends upon time-varying incident radiation, cell temperature, and cell defects.

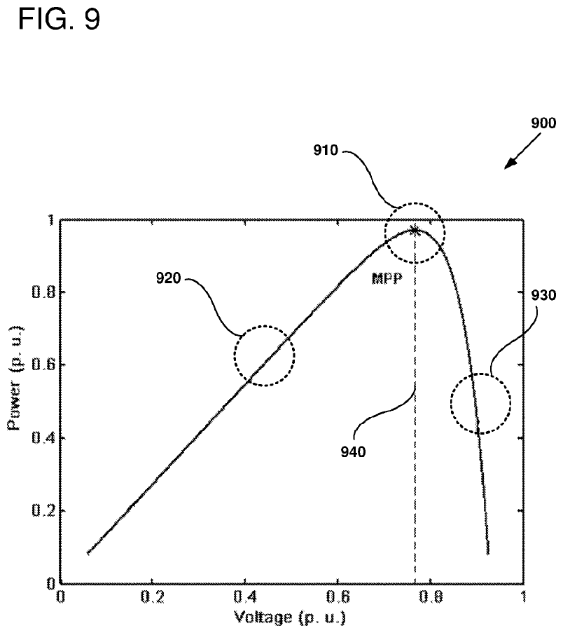

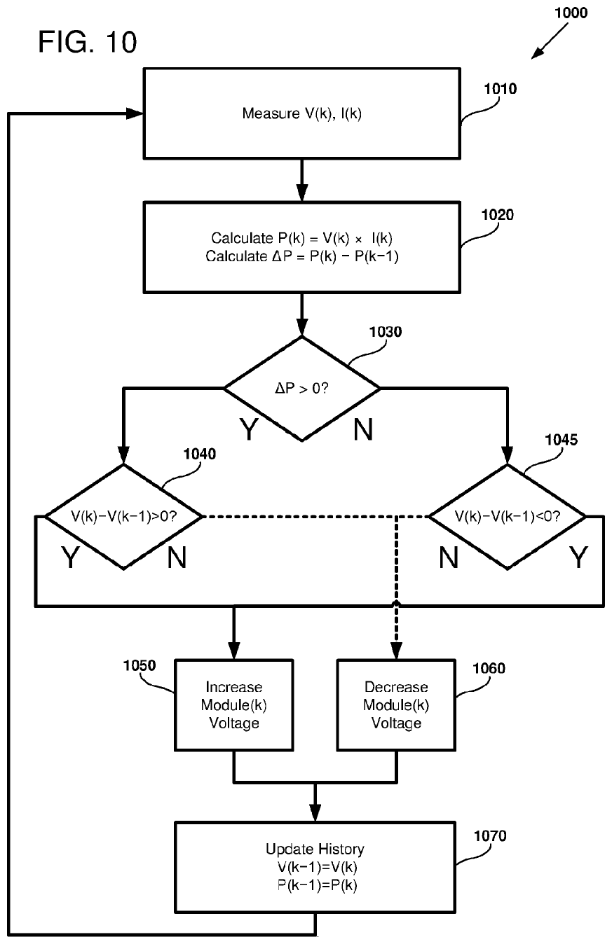

FIG. 9 is a chart 900 plotting the power output of a photovoltaic cell vs. voltage across the photodiode. As shown, the maximum power output for the cell from a particular material is realized when the voltage output of the converter in the range of about 0.75V as shown about dashed region 910. When the PV cell is operated at other output voltages, the power output is reduced. For example, when the voltage output is in the range of about 0.45 V as shown within the dashed region 920, the power is about 40% less than the nominal maximum power. From this range, the output voltage of the PV cell should be increased in order to increase its output power. When the voltage output is in the range of about 0.9 V, as shown at 930, the output voltage of the PV cell should be decreased in order to increase the PV cell's output power. A maximum power point or range can be determined dynamically by the controller using any suitable control technique. For example, perturb and observe methods as disclosed with respect to FIG. 10 can be used to adjust the output voltage towards a desired power output level. For example, when the power and voltage output indicate the power converter is operating left of the dash line 940, the controller seeks to increase the voltage output of the converter. When the power and voltage output indicated the power converter is operating right of the dashed line 940, the controller seeks to decrease the voltage output of the converter. In this way, the controller seeks to operate the power converter close to the maximum power point region 910.

### VI. Example of Operating a Power Converter with a Controller

FIG. 10 is a flow chart 1000 outlining an example method of operating a power converter with a controller. For example, the systems discussed above and below can be adapted to perform the illustrated method. In general, the controller applies a “perturb and observe” approach to regulating an isolated power converter coupled to a PV cell. An optimization goal of the method is to operate the power converter so that its PV cell is at or close to its maximum power point (MPP). In some examples, the controller controls a single power converter at a time. In other examples, plural power converter's can be controlled at the same time. For ease of explanation, this method shows operations that are performed after a single power converter has been selected to be adjusted.

At process block 1010, the controller measures instantaneous voltage (V(k)) and current (I(k)) produced by a power converter. Any suitable method of measuring the voltage across the output terminals of the zonal power converter and the current draw from the output may be used. At process block 1020, the controller calculates the power P(k) as the product of voltage and current, and the calculates the difference in power ΔP between the current sample and the previous sample k−1.

At decision block 1030, if the power difference ΔP is greater than zero (indicating increasing power output over the previous sample) then the method proceeds to decision block 1040 and the current voltage measurement is compared to previous voltage sample(s). With reference to the example of FIG. 9, if the voltage is increasing (ΔV is greater than zero) this suggests the converter is operating to the left of its MPP region. (As an example, when the converter is operating around dashed region 920.) The controller proceeds to process block 1050 to increase the module output voltage toward the MPP by appropriately modulating the converter's control signal. For example, the module voltage of a flyback converter can be increased by increasing the portion of the duty cycle that the switch is open. If on the other hand, the voltage is decreasing (ΔV is less than zero), this suggests the converter is operating to the right of its MPP region 910. (As an example, when the converter is operating around dashed region 930.) So, the controller proceeds to process block 1060 to decrease the module output voltage by appropriate modulation of the controller's control signal at process block 1060.

If the power difference ΔP is less than zero at decision block 1030 (indicating decreasing power over the previous sample) then the method proceeds to decision block 1045 and the current voltage is compared to the previous voltage sample. With reference to the example of FIG. 9, if the voltage is decreasing, this suggests the converter is operating to the left of its MPP (e.g., converter is operating around dashed region 920), and then the controller proceeds to process block 1050 to increase the module voltage using similar methods as the preceding paragraph. Conversely, if the voltage is increasing, the converter is operating to the right of the MPP and the controller proceeds to process block 1060 to decrease the module voltage.

After updating the module output voltage by appropriate adjustment of the converter's control signal, the method proceeds to process block 1070 and the controller updates the history information by storing the current voltage and power for comparison. At a later time, the controller will reiterate the illustrated method by proceeding to process block 1010 and measuring voltage and current again, etc.

It should be noted that the illustrated method shows operations performed to adjust one of the converters to output closer to its maximum power point. The controller can then proceed to perform the illustrated method for another converter in the circuit, adjusting the control signal until a maximum power point is found for the next converter.

In another example, the controller measures voltage of each zonal output and measures output current using, for example, Hall current sensors. The controller can concurrently adjust signals to each zone and continuously maintain MPP for each zone.

### VII. Example Computing Environment

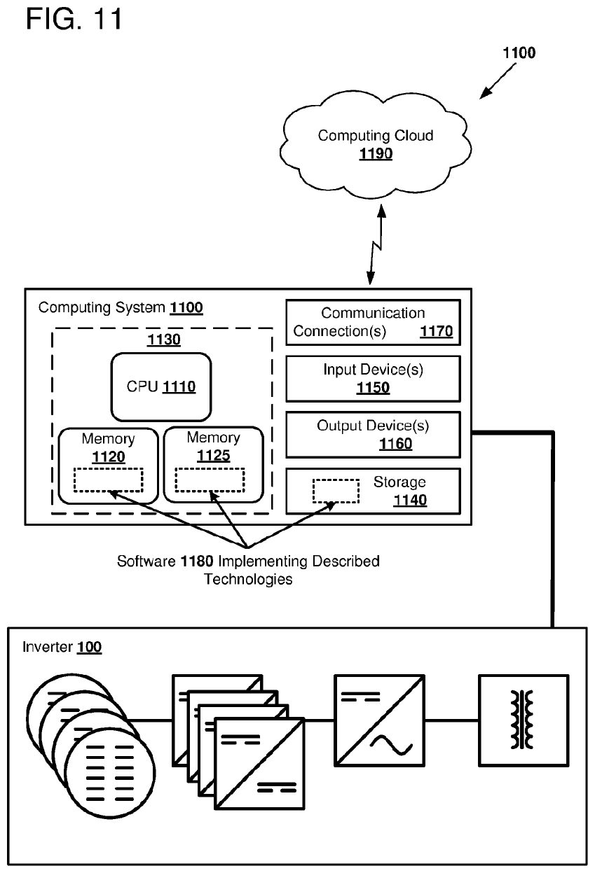

FIG. 11 illustrates a generalized example of a suitable computing environment 1100 in which described embodiments, techniques, and technologies, including implementing microcontrollers for a power inverter, can be implemented. For example, the computing environment 1100 can be used to implement any of the microcontrollers or processors, as described herein.

The computing environment 1100 is not intended to suggest any limitation as to scope of use or functionality of the technology, as the technology may be implemented in diverse general-purpose or special-purpose computing environments. For example, the disclosed technology may be implemented with other computer system configurations, including hand-held devices, multiprocessor systems, microprocessor-based or programmable consumer electronics, network PCs, minicomputers, mainframe computers, and the like. The disclosed technology may also be practiced in distributed computing environments where tasks are performed by remote processing devices that are linked through a communications network. In a distributed computing environment, program modules may be located in both local and remote memory storage devices.

With reference to FIG. 11, the computing environment 1100 includes at least one central processing unit 1110 and memory 1120, 1125. In FIG. 11, this most basic configuration 1130 is included within a dashed line. The central processing unit 1110 executes computer-executable instructions and may be a real or a virtual processor. The central processing unit 1110 can be a general-purpose microprocessor, a microcontroller, or other suitable processor. In a multi-processing system, multiple processing units execute computer-executable instructions to increase processing power and as such, multiple processors can be running simultaneously. The memory 1120, 1125 may be volatile memory (e.g., registers, cache, RAM), non-volatile memory (e.g., ROM, EEPROM, flash memory, etc.), or some combination of the two. The memory 1120, 1125 stores software 1180, parameters, and other data that can, for example, implement the technologies described herein. A computing environment may have additional features. For example, the computing environment 1100 includes storage 1140, one or more input devices 1150, one or more output devices 1160, and one or more communication connections 1170. The computing environment 1100 can be coupled to a power inverter 100, as discussed in further detail above. An interconnection mechanism (not shown) such as a bus, a controller, or a network, interconnects the components of the computing environment 1100. Typically, operating system software (not shown) provides an operating environment for other software executing in the computing environment 1100, and coordinates activities of the components of the computing environment 1100.

The storage 1140 may be removable or non-removable, and includes magnetic disks, magnetic tapes or cassettes, CD-ROMs, CD-RWs, DVDs, or any other medium which can be used to store information and that can be accessed within the computing environment 1100. The storage 1140 stores instructions for the software 1180, which can be used to implement technologies described herein. As used herein, computer-readable storage media include tangible media including memory and storage, but does not consist of non-transitory media or signals.

The input device(s) 1150 may be a touch input device, such as a keyboard, keypad, mouse, touch screen display, pen, or trackball, a voice input device, a scanning device, or another device, that provides input to the computing environment 1100. For audio, the input device(s) 1150 may be a sound card or similar device that accepts audio input in analog or digital form, or a CD-ROM reader that provides audio samples to the computing environment 1100. The input device(s) 1150 can also include sensors and other suitable transducers for generating data about the PV cells or converters, for example, voltage measurements, frequency measurements, current measurements, temperature, and other suitable sensor data. The output device(s) 1160 may be a display, printer, speaker, CD-writer, or another device that provides output from the computing environment 1100. The output device(s) 1160 can also include interface circuitry for sending commands and signals to the generators, for example, to increase or decrease field excitation voltage or output voltage of the generator.

The communication connection(s) 1170 enable communication over a communication medium (e.g., a connecting network) to another computing entity. The communication medium conveys information such as computer-executable instructions, compressed graphics information, video, or other data in an adjusted data signal. The communication connection(s) 1170 are not limited to wired connections (e.g., megabit or gigabit Ethernet, Infiniband, Fibre Channel over electrical or fiber optic connections) but also include wireless technologies (e.g., RF connections via Bluetooth, WiFi (IEEE 802.11a/b/n), WiMax, cellular, satellite, laser, infrared) and other suitable communication connections for providing a network connection for the disclosed controllers and coordinators. Both wired and wireless connections can be implemented using a network adapter. In a virtual host environment, the communication(s) connections can be a virtualized network connection provided by the virtual host. In some examples, the communication connection(s) 1170 are used to supplement, or in lieu of, the input device(s) 1150 and/or output device(s) 1160 in order to communicate with the DC/DC converters, DC/AC converters, or other controlled devices.

Some embodiments of the disclosed methods can be performed using computer-executable instructions implementing all or a portion of the disclosed technology in a computing cloud 1190.

Computer-readable media are any available media that can be accessed within a computing environment 1100. By way of example, and not limitation, with the computing environment 1100, computer-readable media include memory 1120 and/or storage 1140. As should be readily understood, the term computer-readable storage media includes the media for data storage such as memory 1120 and storage 1140, and not transmission media such as adjusted data signals.

### VIII. Additional Example Zonal Inverter System Including Multi-Input Transformer

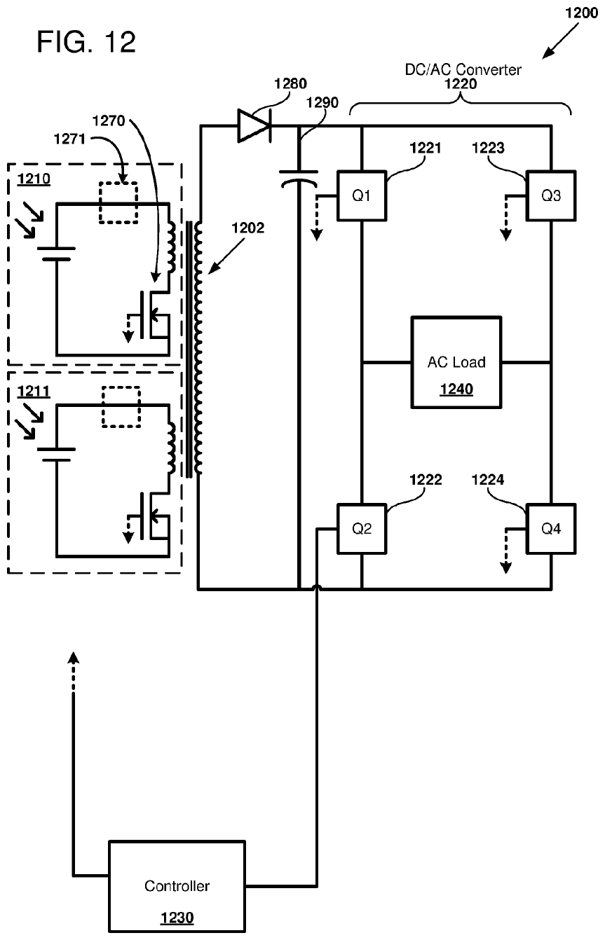

FIG. 12 is a simplified schematic of a photovoltaic converter system 1200 including a multi-input transformer 1202, as can be implemented in certain examples of the disclosed technology. Similar to the photovoltaic converter system 200 discussed above regarding FIGS. 2A-2B, each of the converter units 1210, 1211 is coupled to a photovoltaic cell which produces charge in response to incident photons received at the active layer(s) of the cell. The photovoltaic cell acts as a variable DC voltage source. The outputs of each of the converter units is coupled to a different respective input of the primary coil of the multi-input transformer 1202. The multi-input transformer depicted in FIG. 12 has multiple windings on the primary coil. The other end of the primary coil input is coupled to a switch (for example, switch 1270 of converter unit 1210). When the switch is closed, it completes the circuit to the other terminal of the PV cell. The dashed lines indicate an alternate configuration 1271 for placing a switching between the output of the photovoltaic cell and the converter's respective input to the transformer 1202.

Each of the flyback converter units 1210, 1211 is electrically isolated from each other. As shown, each PV cell or PV zone connects only to its respective voltage converter. When the flyback converters switch is open, the respective PV cell is not electrically connected to its transformer. The controller 1230 modulates an input signal to each of the flyback converter switches to cause the switches to open and close. The controller synchronizes operation of the switches to optimize the total power output of each PV cell, as will be described in further detail below. The multi-input transformer 1202 has a secondary coil that is connected to the input of a diode 1280. The output of the diode 1280 is coupled to a capacitor 1290 and the input of a DC/AC converter 1220.

The controller 1230 also modulates input to the DC/AC converter 1220. In this example, a H-Bridge style DC/AC converter comprising four drivers Q1 1221, Q2 1222, Q3 1223, and Q4 1224 is used, although as will be readily understood to one of ordinary skill in the art, other DC/AC converter circuits may be used. For example, a cascaded H-bridge converter can provide the DC/AC converter. The DC/AC converter 1220 is configured to drive an AC load 1240 at its output.

### IX. Additional Example Zonal Inverter System Including Groups of Converters

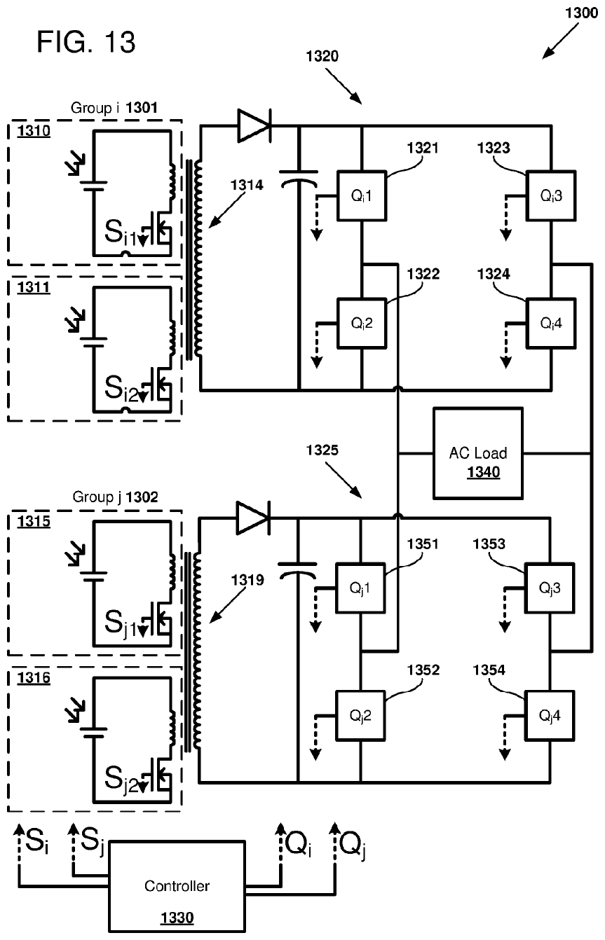

FIG. 13 is a simplified schematic of a photovoltaic converter system 1300 including multiple driver groups 1301, 1302, as can be implemented in certain examples of the disclosed technology. Similar to the photovoltaic converter system 1200 discussed above regarding FIG. 12, Group i 1301 includes a plurality of converter units 1310, 1311, each coupled to a respective photovoltaic cell which produces charge in response to incident photons received at the active layer(s) of the cell. The photovoltaic cell acts as a variable DC voltage source. The outputs of each of the converter units 1310, 1311 is coupled to a different respective input of the primary coil of the multi-input transformer 1314. The other end of each respective primary coil input is coupled to a respective switch (e.g., switch Sᵢ₁ or Sᵢ₂). When the synchronized switches Sᵢ₁,Sᵢ₂, etc., are closed, it completes the circuit to the other terminal of the PV cell. In alternative examples, the switch can be placed between the output of the photovoltaic cell and the converter's respective input to the multi-input transformer 1314. In an alternative configuration, each PV cell or zone is connected to separate transformers, and the outputs of these transformers are connected in series.

Group j 1302 includes a plurality of converter units 1315, 1316, each coupled to a respective photovoltaic cell which produces charge in response to incident photons received at the active layer(s) of the cell. The outputs of each of the converter units 1315, 1316 is coupled to a different respective input of the primary coil of the multi-input transformer 1319. The photovoltaic cells coupled to each group can be selected to possesses similar I-V characteristics (e.g., semiconductor bandgap, illumination, and/or temperature). The input switches of the converters within each respective Group 1301, 1302 are synchronized together. As shown in FIG. 13, the transformer outputs of Group j 1302 are serially connected to the same diode/capacitor and load, which in turn is coupled to a respective DC/AC converter 1320, 1325 to transfer power to the AC load 1340. Within the inverter system, Groups can be configured to transfer their DC power at a selected maximum power point and convert to an AC load 1340. As shown in FIG. 13, these loads can be same load and phase. In other examples, the outputs of the respective groups are applied to the same load at a different phase, or different loads at different phases. In an alternative configuration, each PV cell or zone is connected to separate transformers, and the outputs of these transformers are connected in series.

Each of the flyback converters in the group 1301 (converters units 1310, 1311) and group 1302 (converter units 1315, 1316) are electrically isolated from each other. As shown, each PV cell or PV zone connects only to its respective voltage converter. When the flyback converters switch is open, the respective PV cell is not electrically connected to its transformer. The controller 1330 modulates an input signal to each of the flyback converter switches to cause the switches to open and close. The controller attempts to optimize the power output of each PV group, as will be described in further detail below. The multi-input transformers have a secondary coil that is connected to the input of a diode. For Group i, the output of the diode is coupled to a capacitor and the input of a DC/AC converter 1320. For Group j, the output of the diode is coupled to a capacitor and the input of a DC/AC converter 1325.

The controller 1330 also modulates input to the DC/AC converter 1320. In this example, Group i 1301 includes an H-Bridge style DC/AC converter comprising four drivers Q1 1321, Q2 1322, Q3 1323, and Q4 1324 is used, although as will be readily understood to one of ordinary skill in the art, other DC/AC converter circuits may be used. For example, a cascaded H-bridge can provide the DC/AC converter. Group i's four drivers Q1 1321, Q2 1322, Q3 1323, and Q4 1324 are coupled to its multi-input transformer 1314. Similarly, Group j 1302 includes an additional four drivers Q1 1351, Q2 1352, Q3 1353, and Q4 1354 coupled to the outputs of its multi-input transformer 1319. The drivers are modulated by the controller to 1330 to drive the AC load 1340.

### X. Additional Examples of the Disclosed Technology

Additional examples of the technology are disclosed herein as follows. In some examples, a system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes an apparatus may include a zonal power inverter. The apparatus also includes the power inverter may include a plurality of voltage converters, each of the plurality of voltage converters having: input terminals may include a positive input terminal and a negative input terminal, output terminals may include a positive output terminal and a negative output terminal, a switch having a control input to open and close the switch responsive to a signal received by the control input, and a first switch terminal electrically connected to the positive output terminal or the negative output terminal, and the output terminals of the voltage converters being connected in series, each of the voltage converters being electrically isolated from one another except for their output terminals being connected in series. The apparatus also includes a dc/ac converter coupled to a positive output terminal of one of the voltage converters and a negative output terminal of one of the voltage converters. The apparatus also includes a plurality of photovoltaic (PV) cells, each of the PVcells having a cathode coupled to the positive input terminal of a respective one of the voltage converters and an anode coupled to the negative input terminal of its respective one of the voltage converters. The apparatus also includes a controller coupled to the respective control inputs of the voltage converter switches, the controller being programmed to modulate each of the respective control inputs to regulate output voltage at the respective output terminal the voltage converters. Other embodiments of this aspect include corresponding computer systems, apparatus, and computer programs recorded on one or more computer storage devices, each configured to perform the actions of the methods. Implementations can include one or more aspects according to the following clauses:
Clause 1. An apparatus comprising a zonal power inverter: the power inverter comprising a plurality of voltage converters, each of the plurality of voltage converters having: input terminals comprising a positive input terminal (+Vᵢₙ) and a negative input terminal (−Vᵢₙ), output terminals comprising a positive output terminal (+Vₒᵤₜ) and a negative output terminal (−Vₒᵤₜ), a switch having a control input to open and close the switch responsive to a signal received by the control input, and a first switch terminal electrically connected to the positive output terminal (+Vₒᵤₜ) or the negative output terminal (−Vₒᵤₜ), and the output terminals of the voltage converters being connected in series, each of the voltage converters being electrically isolated from one another except for their output terminals being connected in series; a DC/AC converter coupled to a positive output terminal (+Vₒᵤₜ) of one of the voltage converters and a negative output terminal (−Vₒᵤₜ) of one of the voltage converters; and a plurality of photovoltaic (PV) cells, each of the PV cells having a cathode coupled to the +Vᵢₙ input terminal of a respective one of the voltage converters and an anode coupled to the −Vᵢₙ input terminal of its respective one of the voltage converters; and a controller coupled to the respective control inputs of the voltage converter switches, the controller being programmed to modulate each of the respective control inputs to regulate output voltage at the respective output terminal the voltage converters.
Clause 2. The apparatus of clause 1, wherein at least one of the voltage converters is selected from at least one of the following types: flyback DC/DC converter, isolated ĆUK, isolated SEPIC (single-ended primary-inductor converter), Zeta (inverse SEPIC), push-pull, forward, dual-active bridge (DAB), dual-half bridge, half-full bridge, or multiport DAB.
Clause 3. The apparatus of clause 2, the at least one voltage converter further comprising: a transformer having a primary coil and a secondary coil, the terminals of the primary coil being coupled to the (+Vᵢₙ) terminal and a second terminal of the switch, the switch electrically connecting its first terminal and second terminal when closed responsive to the control input.
Clause 4. The apparatus of clause 3, wherein a first terminal of the secondary coil is electrically coupled to the positive output terminal (+Vₒᵤₜ) of the at least one voltage converter and a second terminal of the secondary coil is electrically coupled to the negative output terminal (−Vₒᵤₜ) of the at least one voltage converter.
Clause 5. The apparatus of clause 4, further comprising a diode having an anode and a cathode, wherein the first terminal of the secondary coil is connected to the anode of a diode, and wherein the second terminal of the secondary coil is electrically connected to the negative output terminal (−Vₒᵤₜ) of the at least one voltage converter.
Clause 6. The apparatus of clause 4, wherein the switch is a first switch, the apparatus further comprising a second switch coupled to the first terminal of the secondary coil, the second switch being configured to operate in opposite phase to the first switch.
Clause 7. The apparatus of clause 6, further comprising a diode connected in parallel with the second switch.
Clause 8. The apparatus of any one of clauses 1-7, wherein the DC/AC converter is an H-bridge converter controlled by the controller.
Clause 9. The apparatus of any one of clauses 1-7, wherein the controller is programmed to modulate each of the respective control inputs by modulating duty cycles of the respective control inputs.
Clause 10. The apparatus of any one of clauses 1-7, wherein the PV cells are a region within a multi-junction, electrically isolated PV cell.
Clause 11. The apparatus of clause 1, wherein the controller is programmed to: measure an output voltage across the output terminals of each of the voltage converters and current output of each of the voltage converters, and responsive to output power and the output voltage of a respective voltage converter, modulate the voltage converter's respective switch control input to drive to maintain a maximum output power.
Clause 12. The apparatus of clause 1111, wherein the controller is further programmed to modulate the respective switch control input to maintain the output voltage based on a desired power output level of the respective electrical controller.
Clause 13. The apparatus of clause 11, wherein the controller is further programmed to modulate the respective switch control input to maintain the output power at a maximum power point for the respective PV cell.
Clause 14. The apparatus of clause 11, wherein the output voltage is based on a type of the PV cell coupled to the voltage converter.
Clause 15. The apparatus of clause 14, wherein the switch is a microelectromechanical (MEM) switch, a depletion mode field effect transistor (FET), a depletion mode metal oxide semiconductor FET (MOSFET), an enhancement mode FET, an enhancement mode MOSFET, a mechanical switch, or a relay.
Clause 16. A method comprising: with a controller, modulating input signals to a plurality of voltage converters coupled in series, each of the plurality of voltage converters being electrically isolated except for the series coupling and being configured to receive power from a respective photovoltaic (PV) cell of a plurality of photovoltaic cells.
Clause 17. The method of clause 16, wherein the modulating input signals comprises measuring a voltage and a current at an output of the respective voltage converter.
Clause 18. The method of clause 16, further comprising providing the plurality of voltage converters and the plurality of PV cells.
Clause 19. The method of clause 16, wherein the modulating input signals are generated using pulse width modulation (PWM).
Clause 20. The method of clause 16, wherein the controller is a proportional-integral-derivative (PID) controller, a microcontroller, or a field-programmable gate array (FPGA).
Clause 21. The method of clause 16, wherein the controller is a proportional-integral (PI) controller, microcontroller, field-programmable gate array (FPGA), or an ASIC-based controller.
Clause 22. The method of clause 16, further comprising applying liquid or gas to a substrate of at least one of the plurality of photovoltaic cells.
Clause 23. The method of clause 16, further comprising: coupling the voltage converters and the PV cells to the controller.
Clause 24. The method of clause 16, further comprising: manufacturing a PV module comprising the controller and the PV cells.
Clause 25. The method of clause 16, further comprising: transmitting power generated with the PV cells using the controller and the voltage converters to an electrical power grid.
Clause 26. Computer-readable storage media storing computer-readable instructions, which when executed by a computer, cause the computer to perform the method of any one of clauses 16-25.
Clause 27. The computer-readable storage media of clause 26, wherein the computer comprises: a processor; memory; and an input/output (I/O) interface to the voltage converters.
Clause 28. An isolated multi-junction photovoltaic (PV) cell, comprising: a plurality of photosensitive semiconductor active layers, each of the active layers being: electrically isolated from the other active layers, and formed from a respective material having a different band gap than the other active layers.
Clause 29. The PV cell of clause 28, wherein the active layers comprise at least one of the following: an active layer comprising at least one of: boron phosphide, selenium, lanthanum copper oxide, selenium, cadmium selenide, Perovskite, copper indium gallium diselenide (CIGS), aluminum antimonide, tin sulfide, zinc phosphide, cadmium telluride, copper zinc tin sulfide (CZTS), gallium arsenide, or indium phosphide; and an active layer comprising at least one of tin sulfide, boron arsenide, silicon, copper zinc tin sulfur selenide (CZTSSe), copper indium selenide (CIS), zinc arsenide, iron disulfide, copper tin sulfide (CTS), silver sulfide, gallium antimonide, indium nitride, or germanium.
Clause 30. The PV cell of clause 28, wherein the active layers comprise at least one of the following: an active layer comprising at least one of: Copper (I) oxide, Aluminum arsenide, gallium indium phosphide (GaInP), Zinc diphosphide, gallium selenide, selenium, boron phosphide, or lanthanum copper oxide (La₂CuO₂); an active layer comprising at least one of: selenium, cadmium selenide, Perovskite, copper indium gallium diselenide (CIGS), aluminium antimonide, tin sulfide, zinc phosphide, cadmium telluride, or copper zinc tin sulfide (CZTS); and an active layer comprising at least one of tin sulfide, boron arsenide, silicon, copper zinc tin sulfur selenide (CZTSSe), copper indium selenide (CIS), zinc arsenide, iron disulfide, copper tin sulfide (CTS), silver sulfide, gallium antimonide, indium nitride, or germanium.
Clause 31. The PV cell of clause 28, wherein the active layers comprise at least one of the following: an active layer comprising at least one of: boron phosphide, Lanthanum copper oxide, selenium, Cadmium selenide, Perovskite, or copper indium gallium diselenide (CIGS); an active layer comprising at least one of: cadmium telluride, copper zinc tin sulfide, gallium arsenide, or indium phosphide; an active layer comprising at least one of Tin sulfide, Boron arsenide, Silicon, copper zinc tin sulfur selenide (CZTSSe), Copper indium selenide (CIS), Zinc arsenide, Iron disulfide, copper tin sulfide (CTS), or silver sulfide; and an active layer comprising at least one of gallium antimonide, indium nitride, or germanium.
Clause 32. The PV cell of clause 28, wherein the active layers comprise at least one of the following: an active layer comprising at least one of: Copper (I) oxide, Aluminum arsenide, gallium indium phosphide (GaInP), zinc diphosphide, gallium selenide, selenium, boron phosphide or lanthanum copper oxide (La₂CuO₂); an active layer comprising at least one of: selenium, cadmium selenide, Perovskite, copper indium gallium diselenide (CIGS), or aluminum antimonide; an active layer comprising at least one of: gallium arsenide, indium phosphide or uranium dioxide; an active layer comprising at least one of copper sulfide, copper oxide, tin sulfide, boron arsenide, silicon or copper zinc tin sulfur selenide (CZTSSe); and an active layer comprising at least one of copper indium selenide (CIS), zinc arsenide (Zn₃As₂), iron disulfide, copper tin sulfide (CTS), silver sulfide, gallium antimonide, indium nitride, or germanium.
Clause 33. The PV cell of clause 28, wherein the active layers comprise at least one of the following: an active layer comprising at least one of: copper (I) oxide, aluminum arsenide, gallium indium phosphide (GaInP), zinc diphosphide, gallium selenide, selenium, boron phosphide or lanthanum copper oxide (La₂CuO₂); an active layer comprising at least one of: selenium, cadmium selenide, Perovskite, copper indium gallium diselenide (CIGS), or aluminum antimonide; an active layer comprising at least one of: gallium arsenide, Indium phosphide or uranium dioxide; an active layer comprising at least one of copper sulfide, copper oxide, tin sulfide, boron arsenide, silicon, or copper zinc tin sulfur selenide (CZTSSe); an active layer comprising at least one of copper indium selenide (CIS), zinc arsenide (Zn₃As₂), iron disulfide, copper tin sulfide (CTS), or silver sulfide; and an active layer comprising at least one of gallium antimonide, indium nitride, or germanium.
Clause 34. The PV cell of clause 28, wherein the active layers comprise at least one of the following: an active layer comprising at least one of: boron phosphide, selenium, La₂CuO₂, or gallium indium phosphide; an active layer comprising at least one of: gallium arsenide, cadmium telluride, or copper zinc tin sulfide; an active layer comprising at least one of silicon, tin sulfide, or Zn₃As₂; or an active layer comprising at least one of germanium, indium nitride, or gallium antimonide.
Clause 35. The PV cell of any one of clauses 29-34, further comprising a layer of transparent conductive oxide (TCO) disposed over a surface of the at least one active layer forming an electrical junction with a collector or an emitter of the active layer.
Clause 36. The PV cell of any one of clauses 29-34, further comprising: a first layer of transparent conductive oxide (TCO) disposed over a first surface of the at least one active layer, forming an electrical junction with an emitter of the active layer; and a second layer of TCO disposed over a second, obverse surface of the at least one active layer forming an electrical junction with a collector of the active layer.
Clause 37. The PV cell of any one of clauses 29-35, wherein at least one of the active layers is disposed over a transparent insulating substrate.
Clause 38. The PV cell of any one of clauses 29-35, wherein at least one of the active layers is disposed over a silicon dioxide substrate.
Clause 39. The PV cell of any one of clauses 29-35, further comprising: a first conductor in contact with a first surface of the at least one of the active layers; and a second conductor in contact with a transparent conductive oxide disposed over a second, obverse surface of the at least one of the active layers; wherein the at least one of the active layers is electrically connected to a conductor bus in contact with the at least one of the active layers and a layer of transparent conductive oxide (TCO) disposed over the at least one active layer.
Clause 40. The apparatus of any one of clauses 1-15, wherein at least one of the plurality of photovoltaic cells is one of the isolated multi-junction PV cell of clauses 28-39.
Clause 41. An apparatus comprising a zonal power inverter: the power inverter comprising a plurality of voltage converters, each of the plurality of voltage converters having: input terminals comprising a positive input terminal (+Vᵢₙ) and a negative input terminal (−Vᵢₙ), output terminals comprising a positive output terminal +Vₒᵤₜ and a negative output terminal (−Vₒᵤₜ), a switch having a control input to open and close the switch responsive to a signal received by the control input, and a first switch terminal electrically connected to the (−Vₒᵤₜ) terminal, and the output terminals of the voltage converters being coupled to a respective input of a multi-input transformer, each of the voltage converters being electrically isolated from one another except for their output terminals being coupled to a respective winding of a primary core of the transformer; a DC/AC converter coupled to a positive output terminal (+Vₒᵤₜ) of one of the voltage converters and a negative output terminal (−Vₒᵤₜ) of one of the voltage converters; and a plurality of photovoltaic (PV) cells, each of the PV cells having a cathode coupled to the (+Vᵢₙ) input terminal of a respective one of the voltage converters and an anode coupled to the (−Vᵢₙ) input terminal of its respective one of the voltage converters; and a controller coupled to the respective control inputs of the voltage converter switches, the controller being programmed to modulate each of the respective control inputs to regulate output voltage at the respective output terminal the voltage converters.
Clause 42. The apparatus of clause 41, wherein the DC/AC converter is a first DC/AC converter, the multi-input transformer is a first multi-input transformer, the first DC/AC converter being coupled to the secondary output of the first multi-input transformer, and the apparatus further comprises: a second DC/AC converter, the second DC/AC converter being coupled to a secondary coil output of second multi-input transformer.
Clause 43. The apparatus of clause 42, wherein the first DC/AC converter outputs to a first load and the second DC/AC converter outputs to a different, second load.
Clause 44. The apparatus of clause 42, wherein the first DC/AC converter and the second DC/AC converter outputs to the same load.
Clause 45. The apparatus of clause 42, wherein the first DC/AC converter is configured for a different mode of operation than the second DC/AC converter with respect to at least one of output load or output phase.

In view of the many possible embodiments to which the principles of the disclosed subject matter may be applied, it should be recognized that the illustrated embodiments are only preferred examples and should not be taken as limiting the scope of the scope of the claims to those preferred examples. Rather, the scope of the claimed subject matter is defined by the following claims. I therefore claim as my invention all that comes within the scope of these claims.

1-27. (canceled)

28. An isolated multi-junction photovoltaic (PV) cell, comprising:
a plurality of photosensitive semiconductor active layers, each of the active layers being:
electrically isolated from the other active layers, and
formed from a respective material having a different band gap than the other active layers.

29. The PV cell of claim 28, wherein the active layers comprise at least one of the following:
a first active layer comprising at least one of: boron phosphide, selenium, lanthanum copper oxide, selenium, cadmium selenide, Perovskite, copper indium gallium diselenide (CIGS), aluminum antimonide, tin sulfide, zinc phosphide, cadmium telluride, copper zinc tin sulfide (CZTS), gallium arsenide, or indium phosphide; and
a second active layer comprising at least one of tin sulfide, boron arsenide, copper zinc tin sulfur selenide (CZTSSe), copper indium selenide (CIS), zinc arsenide, iron disulfide, copper tin sulfide (CTS), silver sulfide, gallium antimonide, indium nitride, or germanium.

30. The PV cell of claim 28, wherein the active layers comprise at least one of the following:
a first active layer comprising at least one of: Copper (I) oxide, Aluminum arsenide, gallium indium phosphide (GaInP), Zinc diphosphide, gallium selenide, selenium, boron phosphide, or lanthanum copper oxide (La₂CuO₂);
a second active layer comprising at least one of: selenium, cadmium selenide, Perovskite, copper indium gallium diselenide (CIGS), aluminium antimonide, tin sulfide, zinc phosphide, cadmium telluride, or copper zinc tin sulfide (CZTS); and
a third active layer comprising at least one of tin sulfide, boron arsenide, copper zinc tin sulfur selenide (CZTSSe), copper indium selenide (CIS), zinc arsenide, iron disulfide, copper tin sulfide (CTS), silver sulfide, gallium antimonide, indium nitride, or germanium.

31. The PV cell of claim 28, wherein the active layers comprise at least one of the following:
a first active layer comprising at least one of: boron phosphide, Lanthanum copper oxide, selenium, Cadmium selenide, Perovskite, or copper indium gallium diselenide (CIGS);
a second active layer comprising at least one of: cadmium telluride, copper zinc tin sulfide, gallium arsenide, or indium phosphide;
a third active layer comprising at least one of Tin sulfide, Boron arsenide, copper zinc tin sulfur selenide (CZTSSe), Copper indium selenide (CIS), Zinc arsenide, Iron disulfide, copper tin sulfide (CTS), or silver sulfide; and
a fourth active layer comprising at least one of gallium antimonide, indium nitride, or germanium.

32. The PV cell of claim 28, wherein the active layers comprise at least one of the following:
a first active layer comprising at least one of: Copper (I) oxide, Aluminum arsenide, gallium indium phosphide (GaInP), zinc diphosphide, gallium selenide, selenium, boron phosphide or lanthanum copper oxide (La₂CuO₂);
a second active layer comprising at least one of: selenium, cadmium selenide, Perovskite, copper indium gallium diselenide (CIGS), or aluminum antimonide;
a third active layer comprising at least one of: gallium arsenide, indium phosphide or uranium dioxide;
a fourth active layer comprising at least one of copper sulfide, copper oxide, tin sulfide, boron arsenide, or copper zinc tin sulfur selenide (CZTSSe); and
a fifth active layer comprising at least one of copper indium selenide (CIS), zinc arsenide (Zn₃As₂), iron disulfide, copper tin sulfide (CTS), silver sulfide, gallium antimonide, indium nitride, or germanium.

33. The PV cell of claim 28, wherein the active layers comprise at least one of the following:
a first active layer comprising at least one of: copper (I) oxide, aluminum arsenide, gallium indium phosphide (GaInP), zinc diphosphide, gallium selenide, selenium, boron phosphide or lanthanum copper oxide (La₂CuO₂);
a second active layer comprising at least one of: selenium, cadmium selenide, Perovskite, copper indium gallium diselenide (CIGS), or aluminum antimonide;
a third active layer comprising at least one of: gallium arsenide, Indium phosphide or uranium dioxide;
a fourth active layer comprising at least one of copper sulfide, copper oxide, tin sulfide, boron arsenide, or copper zinc tin sulfur selenide (CZTSSe);
a fifth active layer comprising at least one of copper indium selenide (CIS), zinc arsenide (Zn₃As₂), iron disulfide, copper tin sulfide (CTS), or silver sulfide; and
a sixth active layer comprising at least one of gallium antimonide, indium nitride, or germanium.

34. (canceled)

35. The PV cell of claim 29, further comprising a layer of transparent conductive oxide (TCO) disposed over a surface of the at least one of the active layers forming an electrical junction with a collector or an emitter of the at least one active layer.

36. The PV cell of claim 29, further comprising:
a first layer of transparent conductive oxide (TCO) disposed over a first surface of the first active layer, forming an electrical junction with an emitter of the first active layer; and
a second layer of TCO disposed over a second, obverse surface of the first active layer forming an electrical junction with a collector of the first active layer.

37. The PV cell of claim 29, wherein at least one of the active layers is disposed over a transparent insulating substrate.

38. The PV cell of claim 29, wherein at least one of the active layers is disposed over a silicon dioxide substrate.

39. The PV cell of claim 29, further comprising:
a first conductor in contact with a first surface of the at least one of the active layers; and
a second conductor in contact with a transparent conductive oxide disposed over a second, obverse surface of the at least one of the active layers;
wherein the at least one of the active layers is electrically connected to a conductor bus in contact with the at least one of the active layers and a layer of transparent conductive oxide (TCO) disposed over the at least one active layer.

40-45. (canceled)

46. The PV Cell of claim 29 coupled to a power inverter comprising a plurality of voltage converters, each of the plurality of voltage converters having:
input terminals comprising a positive input terminal (+Vᵢₙ) and a negative input terminal (−Vᵢₙ),
output terminals comprising a positive output terminal (+Vₒᵤₜ) and a negative output terminal (−Vₒᵤₜ),
a switch having a control input to open and close the switch responsive to a signal received by the control input, and a first switch terminal electrically connected to the positive output terminal (+Vₒᵤₜ) or the negative output terminal (−Vₒᵤₜ), and
the output terminals of the voltage converters being connected in series, each of the voltage converters being electrically isolated from one another except for their output terminals being connected in series;
a DC/AC converter coupled to a positive output terminal (+Vₒᵤₜ) of one of the voltage converters and a negative output terminal (−Vₒᵤₜ) of one of the voltage converters; and
a plurality of photovoltaic (PV) cells, each of the PV cells having a cathode coupled to the +Vᵢₙ input terminal of a respective one of the voltage converters and an anode coupled to the −Vᵢₙ input terminal of its respective one of the voltage converters; and
a controller coupled to the respective control inputs of the voltage converter switches, the controller being programmed to modulate each of the respective control inputs to regulate output voltage at the respective output terminal the voltage converters.

47. The PV cell of claim 29, wherein the active layers are disposed over an insulation layer, the insulation layer comprising at least one of silicon dioxide, silicon nitride, aluminum oxide, silicon carbide, or zinc oxide.

48. The PV cell of claim 29, further comprising an insulation layer situated between the first active layer and the second active layer that is manufactured using plasma-enhanced chemical vapor deposition and having a refraction index gradient.

49. The PV cell of claim 35, further comprising a via electrically connecting a top surface of the PV cell to the layer of TCO.

50. An isolated multi-junction photovoltaic (PV) cell, comprising:
a plurality of photosensitive semiconductor active layers, each of the active layers:
being electrically isolated from the other active layers,
being formed from a respective material having a different band gap than the other active layers, and
forming at least one photodiode, the at least one photodiode having a plurality of terminals, each of the terminals being in electrical contact with a respective metal conductor.

51. The PV cell of claim 50, wherein each respective metal conductor is made from aluminum, silver, or copper with an antidiffusion liner.

52. The PV cell of claim 50, wherein a portion of each respective metal conductor forms a trenched finger in a respective one of the active layers.

53. The PV cell of claim 50, wherein a portion of each respective metal conductor forms a trenched finger in an insulation layer.

54. The PV cell of claim 53, wherein the insulation layer comprises at least one of: silicon dioxide, silicon nitride, aluminum oxide, silicon carbide, or zinc oxide.

55. The PV cell of claim 53, wherein each trenched finger is in electrical contact with a respective busbar.

56. The PV cell of claim 50, wherein each of the active layers is manufactured separately on a thin sheet of film and then aligned, thereby forming the PV cell.

57. The PV cell of claim 50, wherein a first one of the active layers comprises a trenched finger formed from a conductor.

58. The PV cell of claim 50, further comprising a first insulation layer below a first one of the active layers, the first insulation layer comprising a trenched finger formed from a conductor.

59. The PV cell of claim 50, further comprising at least one via region having a plurality of vias and connecting each respective metal conductor to a top surface of the PV cell, the metal conductor being formed as a finger, busbar, or transparent conductive oxide (TCO).

60. An isolated multi-junction photovoltaic (PV) cell, comprising:
a plurality of photosensitive semiconductor active layers, each of the active layers:
being electrically isolated from the other active layers, and
forming at least one photodiode, the at least one photodiode having a plurality of terminals, each of the terminals being in electrical contact with a respective metal conductor; and
at least one via region having a plurality of vias and connecting each respective metal conductor to a top surface of the PV cell.

61. The PV cell of claim 60, wherein the at least one via region is situated to be connected to a voltage converter.

62. The PV cell of claim 60, wherein the plurality of vias are formed using reactive ion etching or laser etching.
